(19) United States
(12) Patent Application Publication
(10) Pub. No.: US 2026/0310843 A1
(43) Pub. Date: Oct. 8, 2026

(54) PRODUCT CHANGE REQUIREMENT-DRIVEN FORWARD VARIANT NETWORK MODELING METHOD

(71) Applicant: GUANGDONG UNIVERSITY OF TECHNOLOGY, Guangzhou (CN)

(72) Inventors: Jiewu LENG, Guangzhou (CN); Jiahe LI, Guangzhou (CN); Zean LIU, Guangzhou (CN); Qianwei ZHANG, Guangzhou (CN); Hao LV, Guangzhou (CN); Kailin XU, Guangzhou (CN); Qiang LIU, Guangzhou (CN)

(73) Assignee: GUANGDONG UNIVERSITY OF TECHNOLOGY, Guangzhou (CN)

(21) Appl. No.: 19/460,054

(22) Filed: Jan. 26, 2026

(30) Foreign Application Priority Data
Jul. 23, 2025 (CN) 202511017349.0

(51) Int. Cl. G06F 30/18

(52) U.S. Cl. CPC G06F 30/18

(57) ABSTRACT

A product change requirement-driven forward variant network modeling method, includes: determining a product change requirement; acquiring a change requirement for an existing assembly line; obtaining key components of an existing assembly line as parameter nodes to form a parameter node library; obtaining an association relationship between any two parameter nodes in the parameter node library based on a five-dimensional model, and preliminarily constructing a parameter node network model reflecting an assembly line structure; optimizing the parameter node network model; and constructing a forward variant network to predict and analyze a change propagation path; and utilizing the forward variant network to process the change requirement for the existing assembly line, performing assembly line variant path planning, and guiding and achieving rapid reconfiguration of the existing assembly line. A reconfiguration cycle is shortened, reconfiguration efficiency is improved, unnecessary resource waste is reduced, and reconfiguration costs are reduced.

### CROSS-REFERENCE TO RELATED APPLICATIONS

This application claims priority to Chinese Patent Application No. 202511017349.0 with a filing date of Jul. 23, 2025. The content of the aforementioned application, including any intervening amendments thereto, is incorporated herein by reference.

### TECHNICAL FIELD

The present disclosure belongs to the field of assembly line change, and in particular, relates to a product change requirement-driven forward variant network modeling method.

### BACKGROUND

In today's rapidly evolving market environment, product life cycles are increasingly shortened, and customer requirements for product diversity and customization are increasingly growing. This necessitates frequent product iterations and updates by manufacturing enterprises, leading to severe challenges in achieving flexibility and rapid reconfiguration for assembly lines.

A traditional assembly line reconfiguration method often relies on experiential judgment and extensive trial-and-error, resulting in low efficiency, high costs, and difficulty in accurately predicting impact of changes on production process and product performance. In addition, it is difficult for an existing human-machine collaborative assembly line to perform rapid and efficient reconfiguration in response to fast-changing product requirements. This is primarily reflected in the following aspects:

Difficulty in accurately predicting a scope of change impact: Product changes often have cascading effects. Given complex association relationships among a vast number of components, process flows, and equipment in an assembly line, it is difficult for a traditional method to quickly and accurately analyze the scope and extent of product change impact on various stages of the assembly line. This can easily lead to oversights or misjudgments, resulting in an unreasonable or even failed reconfiguration solution.

Lack of a systematic method for change path Planning: Existing assembly line reconfiguration relies heavily on manual experience, lacking a systematic method to guide change path planning. This leads to low reconfiguration efficiency, a long cycle, and high costs, thereby limiting an ability of an enterprise to respond quickly to market requirements.

Difficulty in balancing a plurality of optimization objectives: Assembly line reconfiguration often requires balancing a plurality of objectives including a change propagation risk, change implementation time, change cost, and the like. An existing method is inadequate for effectively conducting comprehensive optimization, frequently leading to the neglect of some objectives while focusing on others.

Single-dimensional change impact assessment: An existing method often focuses on change assessment from a single dimension, failing to provide a comprehensive and synergistic characterization and analysis of change impacts from a plurality of dimensions including function, structure, behavior, execution, and performance. This results in incomplete and insufficiently deep prediction and evaluation of change impact.

To resolve the aforementioned technical problems, an objective of the present disclosure is to provide a product change requirement-driven “function-structure-behavior-execution-performance” forward variant network modeling method, to achieve rapid, efficient, and intelligent reconfiguration design for human-machine collaborative assembly lines, effectively coping with challenges posed by product changes.

### SUMMARY OF PRESENT INVENTION

An objective of the present disclosure is to provide a product change requirement-driven forward variant network modeling method, to resolve at least one technical problem in the conventional technology.

The technical solution of the present disclosure is as follows:

A product change requirement-driven forward variant network modeling method includes:
determining a product change requirement;
acquiring, according to the product change requirement, a change requirement for an existing assembly line to be changed;
decomposing an existing assembly line according to functional differences of components of the existing assembly line, and obtaining key components of the existing assembly line as parameter nodes to form a parameter node library;
obtaining an association relationship between any two parameter nodes in the parameter node library based on a five-dimensional model, preliminarily constructing a parameter node network model reflecting an assembly line structure to embody a connection relationship between the components;
optimizing the parameter node network model, quantifying the association relationship between any two parameter nodes, obtaining mutual influences between any two parameter nodes, characterizing propagation characteristics of the change requirement in the existing assembly line, and providing data support for subsequent change propagation path prediction and planning; and
constructing a forward variant network to predict and analyze a change propagation path; and utilizing the forward variant network to process the change requirement for the existing assembly line, performing assembly line variant path planning, and guiding and achieving rapid reconfiguration of the existing assembly line.

The acquiring, according to the product change requirement, a change requirement for an existing assembly line includes:
receiving and defining a specific requirement of a product change proposed by a customer or a market; and
evaluating a potential impact of the product change on the existing assembly line, and preliminarily identifying a variant requirement of the existing assembly line to be changed.

The decomposing an existing assembly line according to functional differences of components of the existing assembly line, and obtaining key components of the existing assembly line as parameter nodes to form a parameter node library includes:
decomposing the assembly line according to the functional differences of the components of the assembly line, to obtain at least two functional modules;
decomposing any one functional module to obtain the key components in the functional module; and
using the key components as the parameter nodes, extracting key characteristic parameters of the parameter nodes, and establishing the parameter node library to store attribute information and parameter data of all parameter nodes.

A tuple or a data structure indicates any parameter node and key characteristic parameters thereof as follows: Nodeᵢ=(IDᵢ, nameᵢ, typeᵢ, {Pᵢ₁, Pᵢ₂, . . . , Pᵢₖ}, hierarchyᵢ), where
Nodeᵢ indicates a parameter node i; IDᵢ indicates a unique identifier of the parameter node i; nameᵢ indicates a name of the parameter node i; typeᵢ indicates a node type; {Pᵢ₁, Pᵢ₂, . . . , Pᵢₖ} indicates a set of key characteristic parameters of the parameter node i; and hierarchyᵢ indicates a hierarchical relationship of the parameter node i in the assembly line structure;
the set of key characteristic parameters includes a dimensional parameter and a performance parameter; and
the hierarchical relationship in the assembly line structure includes a top-level function or a final assembly line, the functional module, and the key component.

The obtaining an association relationship between any two parameter nodes in the parameter node library based on a five-dimensional model, preliminarily constructing a parameter node network model reflecting an assembly line structure to embody a connection relationship between the components includes:
utilizing a mapping and representation capability of a set pair theory to perform a quantitative description between any two parameter nodes, and establishing an adjacency matrix A and a weighted adjacency matrix W, including
with respect to the adjacency matrix A,
when there are N parameter nodes, constructing an N×N adjacency matrix A, where Aᵢⱼ indicates whether a dependency relationship exists between the parameter node i and a parameter node j, and N is a natural number; when Aᵢⱼ=1, the parameter node i depends on the parameter node j; and when Aᵢⱼ=0, the parameter node i does not depend on the parameter node j; and
with respect to the weighted adjacency matrix W,
assigning a weight value to the association relationship, and constructing the weighted adjacency matrix W, where Wᵢⱼ indicates strength of the dependency relationship between the parameter node i and the parameter node j.

The optimizing the parameter node network model, quantifying the association relationship between any two parameter nodes, obtaining mutual influences between any two parameter nodes includes:
based on the function-structure-behavior-execution-performance (FSBEP) five-dimensional model, analyzing performance correlation, functional correlation, behavioral correlation, structural correlation, and execution correlation among the parameter nodes;
utilizing a mapping and representation capability of a set pair theory to perform a quantitative description of association relationships among the parameter nodes, and establishing a relationship equation set and a mapping matrix among the parameter nodes;
assigning weight values to association relationships of different types according to the strength of the association relationships, to reflect a degree of influence of the change propagation; and
based on the quantified association relationship and the weight values, constructing a change propagation model to dynamically reflect a transfer and diffusion mechanism of the change requirement in the parameter node network.

The constructing a forward variant network to predict and analyze a change propagation path includes:
according to an actual production condition of the existing assembly line to be changed, determining an optimization objective for change propagation path planning, where the optimization objective includes but is not limited to minimizing a change propagation risk, minimizing change propagation time, and minimizing change propagation cost;
according to the optimization objective, establishing a mathematical model for the change propagation path planning, where the mathematical model is based on the parameter node network, a change propagation risk, change propagation time, and change propagation cost are taken as an optimization objective function, and structural parameters and process parameters of the existing assembly line to be changed are taken as constraint conditions;
the optimization objective function is min(αFᵣᵢₛₖ+βFₜᵢₘₑ+γF_{cost}),
where, α+β+γ=1.

Fᵣᵢₛₖ is a minimized change propagation risk; Fₜᵢₘₑ is a minimized change propagation time; and F_{cost} is a minimized change propagation cost; and
based on the mathematical model for change propagation path planning, employing an optimization algorithm to solve for an optimal change propagation path, to generate an assembly line variant path planning solution.

The optimization algorithm includes:
one or more of a genetic algorithm, an ant colony algorithm, or a particle swarm optimization.

The present disclosure at least has the following beneficial effects:

To overcome the aforementioned shortcomings of the conventional technology, the product change requirement-driven forward variant network modeling method provided in the present disclosure can achieve rapid analysis and optimization of assembly line changes through construction of a network model and a path planning method, thereby shortening a reconfiguration cycle and improving reconfiguration efficiency. In addition, systematic change path planning is employed to optimize a reconfiguration solution, reduce unnecessary resource waste, and lower reconfiguration costs. In addition, through forward variant network modeling enhances, adaptability of the assembly line to product changes is enhanced and flexibility of the assembly line is improved, allowing the assembly line to respond quickly to diverse product demands. The method described in the present disclosure provides a theoretical foundation and technical support for intelligent reconfiguration design of the assembly line, laying a foundation for achieving automated and intelligent assembly line reconfiguration in the future.

### BRIEF DESCRIPTION OF THE DRAWINGS

FIG. 1 is a block diagram of a product change requirement-driven forward variant network modeling method according to the present disclosure; and

FIG. 2 is a schematic flowchart of a product change requirement-driven forward variant network modeling method according to the present disclosure.

### DETAILED DESCRIPTION OF THE EMBODIMENTS

This application is further described below with reference to the accompanying drawings.

### Embodiment 1

The present disclosure provides an embodiment.

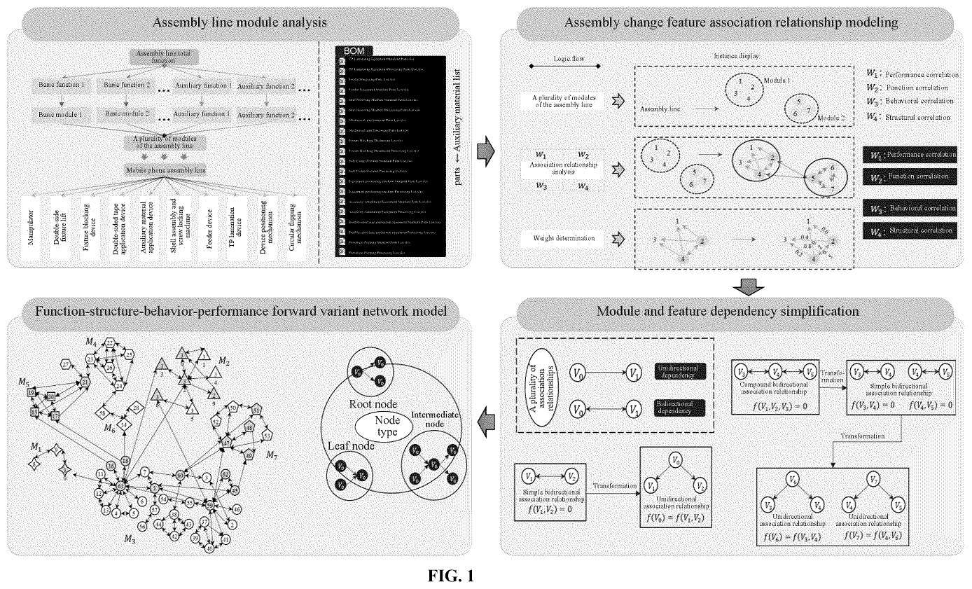

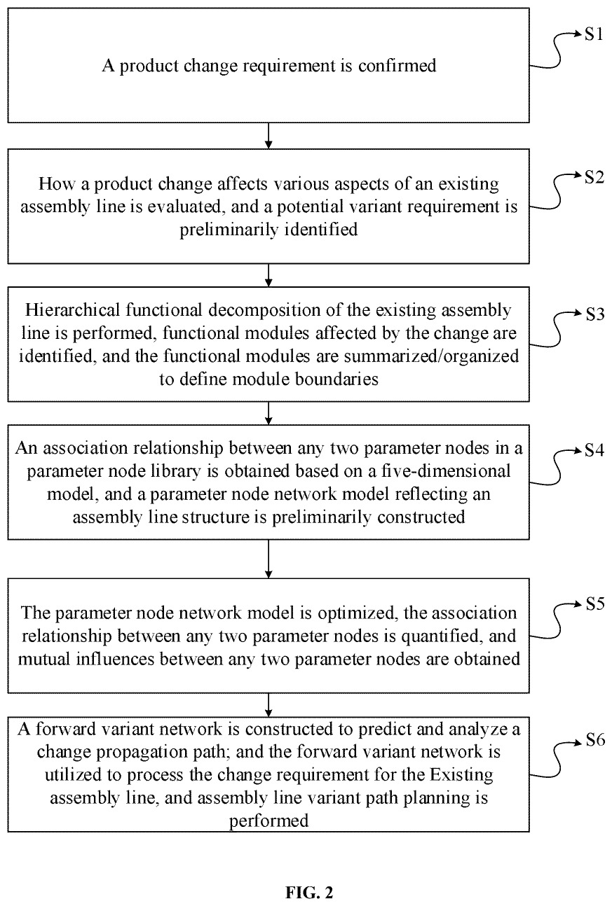

As shown in FIG. 1, the present disclosure provides a product change requirement-driven forward variant network modeling method. Its core idea is to construct an assembly line parameter node network based on a “function-structure-behavior-execution-performance” five-dimensional model, analyze propagation paths of product changes in the assembly line parameter node network, perform change path planning based on multi-objective optimization, and ultimately achieve rapid forward variant reconfiguration of the assembly line. This method primarily includes the following steps, as shown in FIG. 2.

In step S1, a product change requirement is confirmed: A specific requirement of a product change proposed by a customer or a market is received and defined.

In step S2, how a product change affects various aspects of an existing assembly line is evaluated, and a potential variant requirement is preliminarily identified according to the following steps.

A specific requirement of a product change proposed by a customer or a market is received and defined.

A potential impact of the product change on the existing assembly line is evaluated, and the variant requirement of the existing assembly line to be changed is preliminarily identified.

In step S3, hierarchical functional decomposition of the existing assembly line is performed, functional modules affected by the change are identified, and the functional modules are summarized/organized to define module boundaries. Refer to the “assembly line module analysis” section in FIG. 1.

In step S301, according to the functional differences of various parts of the assembly line, the assembly line is decomposed into functional modules. The entire assembly line is divided into several functional modules that can mainly be categorized into two types: basic functional modules and auxiliary functional modules, for example, a material supply module, an assembly module, a detection module, and a handling module.

In step S302, for each functional module, structural module decomposition is performed to determine key components constituting that functional module, for example, a manipulator, a fixture, a sensor, and a control system.

In step S303, the key components in the assembly line are abstracted as parameter nodes, and key characteristic parameters of the parameter nodes are extracted, for example, a dimensional parameter, a performance parameter, and a control parameter. The parameter nodes can be categorized as root nodes, intermediate nodes, and leaf nodes, reflecting hierarchical relationships and dependencies of components in the assembly line.

In step S304, a parameter node library is established to store attribute information and parameter data of all parameter nodes, providing a data foundation for subsequent network modeling and analysis.

Refer to the “assembly line module analysis” section in FIG. 1, showing hierarchical decomposition of an “overall line function” into “basic functions”, “auxiliary functions”, “basic modules”, and “auxiliary modules”, eventually refined to specific station equipment on a “mobile phone assembly line”, for example, a “manipulator”, and a “double-sided tape application device”. A bill of materials (BOM) table shows parameterized information of components, for example, “TP lamination device standard parts.xlsx”. This parameter information is used to construct the parameter nodes.

In step S4, an association relationship between any two parameter nodes in the parameter node library is obtained based on a five-dimensional model, and a parameter node network model reflecting an assembly line structure is preliminarily constructed to embody a connection relationship between the components. Refer to the “assembly line change feature relationship modeling” section in FIG. 1.

In step S401, based on the function-structure-behavior-execution-performance (FSBEP) five-dimensional model, association relationships between parameter nodes of the assembly line are analyzed. The association relationships can be categorized into the following types:

Performance correlation (W1): An association relationship between performance parameters of the parameter nodes. For example, performance improvement of one component may enhance performance of the entire assembly line.

Functional correlation (W2): A dependency relationship between the parameter nodes in terms of functional realization. For example a function of an upstream station is a prerequisite for a function of a downstream station.

Structural correlation (W4): A physical connection relationship between the parameter nodes, for example, an assembly relationship, and a positional relationship between components.

Behavioral correlation (W3): A mutual influence relationship between the parameter nodes in terms of operational behavior, for example, a change in cycle time of one station affects cycle time of another station.

Execution correlation: A mutual influence between the parameter nodes in terms of execution parameters, for example, a change in accuracy of one device may affect processing quality of another device.

In step S402, the mapping and representation capability of the set pair theory is utilized to quantitatively describe the association relationship between parameter nodes. A relationship equation set and a mapping matrix are constructed to represent a coupling and constraint relationship among components of the assembly line and change features.

In step S403, different weight values, for example, W1, W2, W3, and W4 are assigned based on the strength of the association relationship. The weight values can be determined by methods including expert experience, historical data, simulation analysis, or the like. A higher weight value indicates a stronger association relationship and a greater impact of change propagation.

Refer to the “assembly line change feature relationship modeling” section in FIG. 1. The figure shows logical flow: “A plurality of modules of the assembly” are abstracted into an “assembly line”, then “association relationship analysis” is performed to determine four types of association relationships between the parameter nodes, namely, performance, function, behavior, structural correlation, a “weight determination” is finally performed to assign different weight values to different association relationships. The “example display” section graphically shows parameter node association relationships in and between modules, and lines representing different types of association relationships.

In step S5, the parameter node network model is optimized, the association relationship between any two parameter nodes is quantified, mutual influences between any two parameter nodes are obtained.

In step S501, based on an actual production situation of the enterprise, an objective for change propagation path planning is determined, for example, minimizing a change propagation risk, and reducing risks including a production interruption, quality decline potentially caused by change propagation, or the like.

The change propagation time is minimized: A reconfiguration cycle of the assembly line is shortened to respond rapidly to a product change.

The change propagation cost is minimized: Material, labor, equipment, and other costs are reduced during the reconfiguration process.

In step S502, preference rules for each objective are clarified, for example, for a high-risk change, risk reduction is prioritized. For an urgent product change, time reduction is prioritized. For a cost-sensitive product, cost reduction is prioritized.

In step S503, a mathematical model for change propagation path planning is established. This model is based on the parameter node network, the change propagation risk, the change propagation time, and the change propagation costs are taken as an optimization objective, structural parameters and process parameters of the existing assembly line to be changed are taken as constraint conditions, and an optimization algorithm is used, for example, a genetic algorithm, and an ant colony algorithm, to resolve for the optimal change propagation path.

In step S504, based on a calculation result of the mathematical model, an assembly line variant path planning solution is generated to guide an engineer in performing reconfiguration operations of the assembly line.

Refer to the “module and feature dependency relationship simplification” section in the lower right corner of FIG. 1. The figure shows a simplification process of the module and feature dependency relationship from “a plurality of association relationships” simplified to “unidirectional dependency” and “bidirectional dependency”, and finally to simplified “unidirectional association relationships”. f(Vi)=f(Vj, Vk) and f(Vi, Vj)=0 indicate unidirectional and simple bidirectional association relationships between the parameter nodes, respectively. “Composite bidirectional association relationships” can first be transformed into “simple bidirectional association relationships” and then further into “unidirectional association relationships”. This provides a foundation for subsequent mathematical model establishment and path planning.

In step S6, a forward variant network is constructed to predict and analyze a change propagation path; and the forward variant network is utilized to process the change requirement for the existing assembly line to be changed, and assembly line variant path planning is performed. Refer to the “function-structure-behavior-execution-performance forward variant network model” section in FIG. 1.

Network nodes and connections: Each node in the forward variant network represents an element or state of the assembly line in a specific dimension.

Node types include:

A node is general term for basic units in the forward variant network.

A root node indicates a starting point of a change in a certain stage.

A leaf node indicates a final impact point of a change in a certain stage.

An intermediate node indicates an intermediate state during the propagation of a change across different dimensions.

The connections between nodes indicate coupling and constraint relationships existing between different elements or dimensions, reflecting propagation paths of changes.

In step S601, based on the established parameter nodes and association relationships, a complex network model is constructed. Nodes in the forward variant network indicate components of the assembly line. The connection line between nodes indicates association relationships between components. Weight of a connection line indicates strength of the association relationship.

In step S602, a complex network analysis method is utilized to analyze topological structure characteristics of the forward variant network, for example, a node degree, a clustering coefficient, a path length, and centrality, which are used to evaluate complexity of the assembly line and change propagation characteristics of the assembly line.

In step S603, the relationship equation set and the mapping matrix are embedded into the complex network model to describe parameter dependency relationships and change propagation mechanisms between nodes.

Refer to the “function-structure-behavior-execution-performance forward variant network model” section in the lower left corner of FIG. 1. The figure how a complex network topology structure. Nodes in the forward variant network, for example, circles, triangles, and squares indicate different parameter nodes. Connection lines between nodes indicate association relationships between nodes, and the direction of the arrows indicates the direction of change propagation. M1 to M7 represent different modules. The figure shows the complex connection relationships both in and between modules.

### Embodiment 2

The present disclosure further provides an embodiment.

An electronic apparatus includes: a storage medium and a processing unit. The storage medium is configured to store a computer program. The processing unit is configured to perform data exchange with the storage medium. When performing assembly line production, the processing unit executes the computer program to carry out the steps of the product change requirement-driven forward variant network modeling method as described in Embodiment 1.

The present disclosure further provides an embodiment.

A computer-readable storage medium is provided. The computer-readable storage medium stores a computer program. When the computer program is run, the steps of the product change requirement-driven forward variant network modeling method as described in Embodiment 1 are performed.

In the present disclosure, the computer-readable storage medium may be any tangible medium that includes or stores a program, and the program may be used by or in combination with an instruction execution system, apparatus, or device. In the present disclosure, the computer-readable signal medium may include a data signal propagated in a baseband or as a part of a carrier, and computer-readable program code is carried therein. The propagated data signal may be in various forms, including but not limited to an electromagnetic signal, an optical signal, or any suitable combination thereof. The computer-readable signal medium may alternatively be any computer-readable medium except the computer-readable storage medium. The computer-readable medium may send, propagate or transmit a program used by or used in combination with an instruction execution system, apparatus or device. The program code contained on the computer readable medium may be transmitted using any suitable medium, including but not limited to: wireless, wire, optical fiber, RF, or any suitable combination thereof.

The above disclosure is only the specific implementation scenarios of the present disclosure, but the present disclosure is not limited thereto, and all variations conceivable to those skilled in the art should fall in the protection scope of the present disclosure. The serial numbers in the present disclosure are merely for description and do not represent a preference of the implementation scenarios.

What is claimed is:

1. A product change requirement-driven forward variant network modeling method, comprising:
determining a product change requirement;
acquiring, according to the product change requirement, a change requirement for an existing assembly line;
decomposing the existing assembly line according to functional differences of components of the existing assembly line, and obtaining key components of the existing assembly line as parameter nodes to form a parameter node library;
obtaining an association relationship between any two of the parameter nodes in the parameter node library based on a five-dimensional model, preliminarily constructing a parameter node network model reflecting an assembly line structure to embody a connection relationship between the components;
optimizing the parameter node network model, quantifying the association relationship between any two of the parameter nodes, obtaining mutual influences between any two of the parameter nodes, characterizing propagation characteristics of the change requirement in the existing assembly line, and providing data support for subsequent change propagation path prediction and planning; and
constructing a forward variant network to predict and analyze a change propagation path; and utilizing the forward variant network to process the change requirement for the existing assembly line, performing assembly line variant path planning, and guiding and achieving rapid reconfiguration of the existing assembly line.

2. The product change requirement-driven forward variant network modeling method according to claim 1, wherein the acquiring, according to the product change requirement, a change requirement for an existing assembly line comprises:
receiving and defining a specific requirement of a product change proposed by a customer or a market; and
evaluating a potential impact of the product change on the existing assembly line, and preliminarily identifying a variant requirement of the existing assembly line.

3. The product change requirement-driven forward variant network modeling method according to claim 1, wherein the decomposing an existing assembly line according to functional differences of components of the existing assembly line, and obtaining key components of the existing assembly line as parameter nodes to form a parameter node library comprises:
decomposing the existing assembly line according to the functional differences of the components of the existing assembly line, to obtain at least two functional modules;
decomposing any one of the at least two functional modules to obtain the key components in the one functional module; and
using the key components as the parameter nodes, extracting key characteristic parameters of the parameter nodes, and establishing the parameter node library to store attribute information and parameter data of all the parameter nodes.

4. The product change requirement-driven forward variant network modeling method according to claim 3, wherein
a tuple or a data structure indicates the parameter nodes and the key characteristic parameters as follows:
Nodeᵢ=(IDᵢ, nameᵢ, typeᵢ, {Pᵢ₁, Pᵢ₂, . . . , Pᵢₖ}, hierarchyᵢ), wherein
Nodeᵢ indicates an i^{th} parameter node; IDᵢ indicates a unique identifier of the i^{th} parameter node; nameᵢ indicates a name of the i^{th} parameter node; typeᵢ indicates a node type; {Pᵢ₁, Pᵢ₂, . . . , Pᵢₖ} indicates a set of key characteristic parameters of the i^{th} parameter node; and hierarchyᵢ indicates a hierarchical relationship of the i^{th} parameter node in the assembly line structure;
the set of key characteristic parameters comprises a dimensional parameter and a performance parameter; and
the hierarchical relationship in the assembly line structure comprises a top-level function or a final assembly line, the functional module, and the key component.

5. The product change requirement-driven forward variant network modeling method according to claim 1, wherein the obtaining an association relationship between any two parameter nodes in the parameter node library based on a five-dimensional model, preliminarily constructing a parameter node network model reflecting an assembly line structure to embody a connection relationship between the components comprises:
utilizing a mapping and representation capability of a set pair theory to perform a quantitative description between any two parameter nodes, and establishing an adjacency matrix A and a weighted adjacency matrix W, comprising:
with respect to the adjacency matrix A,
when there are N parameter nodes, constructing an N×N adjacency matrix A, wherein Aᵢⱼ indicates whether a dependency relationship exists between the i^{th} parameter node and a j^{th} parameter node; when Aᵢⱼ=1, the i^{th} parameter node depends on the j^{th} parameter node; and when Aᵢⱼ=0, the i^{th} parameter node does not depend on the j^{th} parameter node; and
with respect to the weighted adjacency matrix W,
assigning a weight value to the association relationship, and constructing the weighted adjacency matrix W, wherein Wᵢⱼ indicates strength of the dependency relationship between the i^{th} parameter node and the j^{th} parameter node.

6. The product change requirement-driven forward variant network modeling method according to claim 1, wherein the optimizing the parameter node network model, quantifying the association relationship between any two parameter nodes, obtaining mutual influences between any two parameter nodes comprises:
based on the five-dimensional model, analyzing performance correlation, functional correlation, behavioral correlation, structural correlation, and execution correlation among the parameter nodes;
utilizing a mapping and representation capability of a set pair theory to perform a quantitative description of association relationships among the parameter nodes, and establishing a relationship equation set and a mapping matrix among the parameter nodes;
assigning weight values to association relationships of different types according to strength of the association relationships, to reflect a degree of influence of change propagation; and
based on the quantified association relationship and the weight values, constructing a change propagation model to dynamically reflect a transfer and diffusion mechanism of the change requirement in the parameter node network model.

7. The product change requirement-driven forward variant network modeling method according to claim 1, wherein the constructing a forward variant network to predict and analyze a change propagation path comprises:
according to an actual production condition of the existing assembly line, determining an optimization objective for change propagation path planning, wherein the optimization objective comprises minimizing a change propagation risk, minimizing a change propagation time, and minimizing a change propagation cost;
according to the optimization objective, establishing a mathematical model for the change propagation path planning, wherein the mathematical model is based on the parameter node network model, the change propagation risk, the change propagation time, and the change propagation cost are taken as an optimization objective function, and structural parameters and process parameters of the existing assembly line are taken as constraint conditions;
the optimization objective function is min(αFᵣᵢₛₖ+βFₜᵢₘₑ+γF_{cost}), wherein
α+β+γ=1;
Fᵣᵢₛₖ is a minimized change propagation risk; Fₜᵢₘₑ is a minimized change propagation time; and F_{cost} is a minimized change propagation cost; and
based on the mathematical model for change propagation path planning, employing an optimization algorithm to solve for an optimal change propagation path, to generate an assembly line variant path planning solution.

8. The product change requirement-driven forward variant network modeling method according to claim 7, wherein the optimization algorithm comprises:
one or more of a genetic algorithm, an ant colony algorithm, or a particle swarm optimization.
